(19) United States
(12) Patent Application Publication
(10) Pub. No.: US 2024/0407272 A1
(43) Pub. Date: Dec. 5, 2024

(54) ELECTRONIC DEVICE

(71) Applicant: STMicroelectronics International N.V., Geneva (CH)

(72) Inventors: Philippe BOIVIN, Venelles (FR); Simon JEANNOT, Grenoble (FR)

(73) Assignee: STMicroelectronics International N.V., Geneva (CH)

(21) Appl. No.: 18/671,774

(22) Filed: May 22, 2024

(30) Foreign Application Priority Data
May 31, 2023 (FR) 2305439

(51) Int. Cl. H10N 70/20; H10B 63/10; H10N 70/00

(52) U.S. Cl. CPC H10N 70/231; H10B 63/10; H10N 70/021; H10N 70/068; H10N 70/821

(57) ABSTRACT

A device includes a phase change memory cell. The memory cell includes a first stack of layers including an intermediate layer of phase change material, a lower insulating layer and an upper insulating layer. The memory cell includes L-shaped first and second conductive elements. The first conductive element extends on a first side wall of the first stack. The second conductive element extends on the second side wall of the stack opposite to the first wall.

This application claims the priority benefit of French patent application number FR2305439, filed on May 31, 2023, entitled “Dispositif électronique”, which is hereby incorporated by reference in its entirety.

### BACKGROUND

### Technical Field

The present disclosure relates generally to electronic devices and more specifically electronic devices including memory cells, more specifically phase change memory cells.

### Description of the Related Art

In an usual phase change memory cell, for example, each memory cell includes a layer of phase change material which is in contact with a resistive element. Phase change materials are materials which can switch between a crystalline phase and an amorphous phase. This switching is triggered by an increase in temperature of the resistive element in which an electric current is passed. The difference in electrical resistance between the amorphous phase of the material and its crystalline phase is used to define at least two memory states, arbitrarily 0 and 1.

The memories are generally in the form of arrays, including lines of words (“wordline”) and lines of bits (“bitline”), for example rows and columns. A memory cell, containing binary information, is located at each crossing of a row and a column.

The information contained in a cell of a phase change memory is for example accessed, or read, by measuring the resistance between the bitline and the wordline of the memory cell.

Phase change memory cells are for example located in interconnection networks. By interconnection network is meant a stack of insulating layers, formed during so-called “back end of line” manufacturing steps, in which are located metal tracks coupled to each other by conductive vias. Preferably, the levels of interconnection network, each including conductive tracks in an insulating layer and conductive vias in an insulating layer, have a constant height. However, known memory cells are too high to be placed between certain levels without locally modifying the height of the level.

There is a need for phase change memory cells having a height less than known phase change memory cells, such that they may be entirely located in one level of an interconnection network.

### BRIEF SUMMARY

Embodiments of the present disclosure provide device and methods that address some of the drawbacks of known electronic devices including phase change memory cells.

One embodiment provides a device including a phase change memory cell, the memory cell including a first stack of layers, the first stack of layers including an intermediate layer of phase change material, a lower insulating layer and an upper insulating layer, the cell including L-shaped first and second conductive elements, the first element extending on a first side wall of the first stack, the second element extending on the second side wall of the stack opposite to the first wall. The layer of phase change material is configured so that at least portion of the layer of phase change layer is configured to change between an amorphous state and a crystalline state to determine a stored data value of the first phase change memory cell.

One embodiment provides a manufacturing method of a device including a phase change memory cell, the method including a step of formation of a first stack of layers, the first stack of layers including an intermediate layer of phase change material, a lower insulating layer and an upper insulating layer, the method further including the formation of L-shaped first and second conductive elements, the first element extending on a first side wall of the first stack, the second element extending on the second side wall of the first opposite to the first wall. The layer of phase change material is configured so that at least portion of the layer of phase change layer is configured to change between an amorphous state and a crystalline state to determine a stored data value of the first phase change memory cell.

According to one embodiment, the intermediate layer has a thickness between 5 nm and 50 nm.

According to one embodiment, the device includes an interconnection network, the cell being located between a lower level and an upper level of the interconnection network, the lower and upper levels being successive.

According to one embodiment, the first conductive element includes a horizontal part lying on a third conductive element of the lower level and a vertical part extending on the side wall of the first stack.

According to one embodiment, a fourth conductive element of the upper level is in contact with an upper end of a vertical part of the second element.

According to one embodiment, a fifth conductive element extends from the upper level to a horizontal part of the second conductive element.

According to one embodiment, the method includes the formation of the lower interconnection level, the formation of a second stack of layers including a first layer in a phase change material between two second insulating layers, the formation of cavities extending through the second stack so as to form the first stack, a wall of each first stack being located on the third element.

According to one embodiment, the method includes the conformal formation of a third layer in the material of the first and second elements, the formation of spacers on the side walls of the first stack and the etching of portions of the third layer that are not located under the spacers.

According to one embodiment, the device includes at least two cells in which the intermediate layers have different thicknesses.

According to one embodiment, the intermediate layer of one of the cells has a thickness between 5 nm and 50 nm and wherein the intermediate layer of the other cell has a thickness between 10 nm and 100 nm.

According to one embodiment, the method includes a step of formation of a layer of thickness equal to the difference between the thicknesses of the intermediate layers of the two cells on the location of the cell having the greater thickness.

According to one embodiment, the device includes sixth L-shaped conductive elements extending through the lower layer of the first stack.

According to one embodiment, the device includes seventh L-shaped conductive elements extending through the upper layer of the first stack.

In one embodiment, a device includes an interconnection network including a lower interconnection level and an upper interconnection level and a first phase change memory cell between the lower interconnection level and the upper interconnection level. The first phase change memory cell includes a first lower insulating layer on the lower interconnection level, a first L-shaped conductive element on a first sidewall of the first lower insulating layer and on a top surface of a first conductive interconnection element in the lower interconnection level, and a second L-shaped conductive element on a second sidewall of the first lower insulating layer. The device includes a second phase change memory cell including a second lower insulating layer on the lower interconnection level, a third L-shaped conductive element on a first sidewall of the first lower insulating layer and on a top surface of a second conductive interconnection element in the lower interconnection level, and a fourth L-shaped conductive element on a second sidewall of the first lower insulating layer. The device includes a layer of phase change material on a top surface of the first lower insulating layer, on a top surface of the second lower insulating layer, and extending unbroken between the first and second lower insulating layers, and in contact with a top surface of the first conductive element and with a top surface of the third conductive element.

In one embodiment, the layer of phase change material is in contact with a side surface of the second conductive element and with a side surface of the fourth conductive element.

In one embodiment, the device includes an upper insulating layer on the layer of phase change material and extending between the first phase change memory cell and the second phase change memory cell.

In one embodiment, the upper insulating layer is in contact with a side surface of the second conductive element and with a side surface of the fourth conductive element.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 shows an embodiment of an electronic device including memory cells;

FIG. 2, FIG. 3, FIG. 4, FIG. 5, FIG. 6 and FIG. 7 show the steps in a manufacturing method of the embodiment shown in FIG. 1;

FIG. 8A shows another embodiment of an electronic device including memory cells;

FIG. 8B shows various states of an example of a memory cell according to the embodiment of FIG. 8A;

FIG. 9 shows a step in the manufacturing method of the embodiment of FIG. 8;

FIG. 10 shows another embodiment of an electronic device including memory cells;

FIG. 11 shows another embodiment of an electronic device including memory cells;

FIG. 12, FIG. 13, FIG. 14 and FIG. 15 show the possible states of the embodiment of FIG. 11; and

FIG. 16 shows another embodiment of an electronic device including memory cells.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

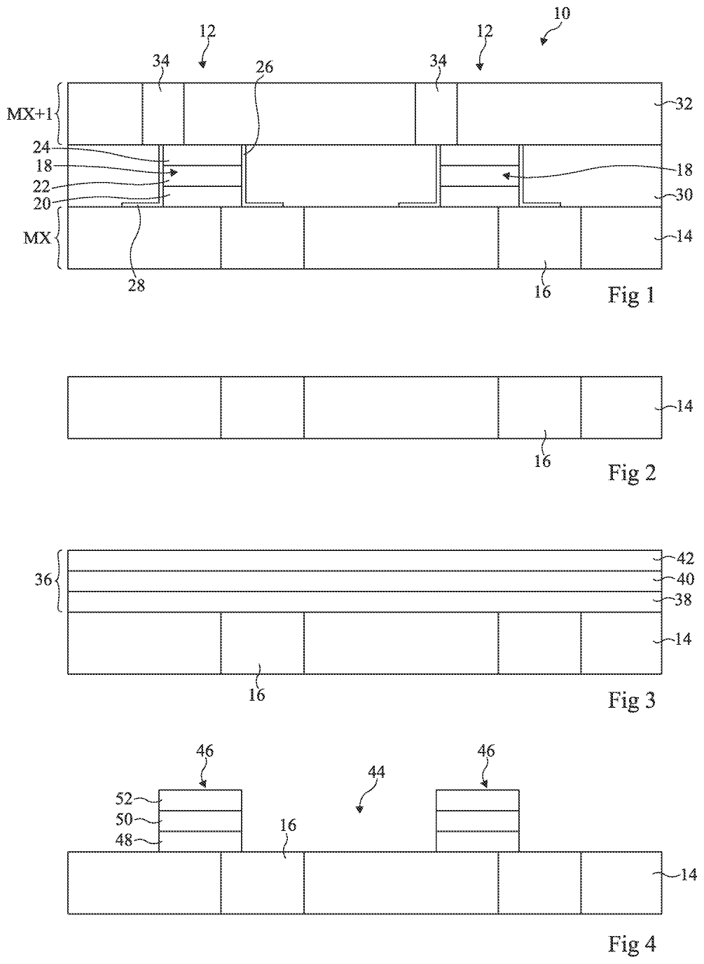

FIG. 1 shows an embodiment of an electronic device 10 including memory cells 12. The device 10 includes for example a plurality of cells 12. The cells 12 are for example, arranged in an array. In the example of FIG. 1, only two cells 12 are shown. The two cells are neighboring cells in the same row of the same column of the array. For example, the two cells are coupled by the same bitline.

The device 10 includes an insulating layer 14. The insulating layer 14 is for example in silicon oxide. The layer 14 is crossed by the conductive elements 16. The elements 16 are for example in metal, for example in copper. The elements 16 preferably extend on the entire height of the layer 14. The elements 16 have for example an upper end coplanar with the upper face of the layer 14.

Layer 14 and elements 16 correspond for example to a level of metallization MX of an interconnection network. The elements 16 have for example a lower end coupled by a via crossing through an insulating layer separating the metallization levels MX and MX-1 with a metallization, for example a metallic strip, extending into the level of metallization MX-1. Each element 16 has for example the form of a strip extending in the direction of a wordline, each cell of the same wordline being coupled to the element 16.

The level MX is for example the lower level ml of an interconnection network, for example the closest level to a semiconductor substrate not shown. For example, selection elements, for example transistors, are formed in and on the substrate not shown. The elements 16 have for example a lower end coupled by a via crossing through an insulating layer separating the layer 14 from the substrate not shown. For example, the lower end of each element 16 is coupled to a terminal of a selection element.

Each cell 12 includes a stack 18 of layers. The layers of the stack 18 preferably have horizontal dimensions, for example in a plane parallel to the upper face of the layer 14, substantially identical. The layers of the stack 18 have side walls coplanar with each other. The side walls of the stack 18 are thus flat.

The stack 18 lies on the layer 14 and on one of the elements 16. More specifically, a side wall of the stack 18 is located on the upper face of an element 16. Another side wall of the stack, preferably the wall opposite to the wall located on the element 16, is located on the insulating layer 14, preferably only on layer 14.

Each stack 18 includes a lower layer 20. The layer 20 is an insulating layer, for example in silicon oxide. The layer 20 extends on the element 16 and on the layer 14.

Each stack 18 includes an intermediate layer 22. The layer 22 is in a phase change material, for example an alloy of germanium, antimony and tellurium (GST). The layer 22 is located on the layer 20, preferably in contact with the layer 20. Preferably, the layer 22 entirely covers the upper face of the layer 20. Preferably, the lower face of the layer 22 is entirely in contact with the upper face of the layer 20.

Each stack 18 includes an upper layer 24. The layer 24 is an insulating layer, for example in silicon oxide. The layer 24 is located on the layer 22, preferably in contact with the layer 22. Preferably, the layer 24 entirely covers the upper face of the layer 22. Preferably, the lower face of the layer 24 is entirely in contact with the upper face of the layer 22.

For example, each stack 18 only includes the layers 20, 22, 24. For example, each stack 18 includes no other conductive or semiconductor layer than layer 22.

Preferably, all the layers 20 have the same thickness. Preferably, all the layers 22 have the same thickness. Similarly, all the layers 24 preferably have the same thickness.

Each cell 12 includes two resistive elements 26 and 28. The elements 26 and 28 are L-shaped. In other words, the elements 26 and 28 each include a horizontal part, preferably flat, and a vertical part, preferably flat.

The element 26 is located on the element 16 associated with the cell. More specifically, the horizontal part of the element 26 extends at least partially, preferably entirely, on the element 16. Thus, the lower face of the horizontal part of the element 26 is in contact with the element 16. The vertical part of element 26 extends on the side wall of the stack 18. More specifically, the vertical part of the element 26 extends on the side wall of the stack 18 located on the element 16. The vertical part of the element 26 extends at least on the side wall of the layer 20 and on at least a part of the side wall of the layer 22. Preferably, the vertical part of the element 26 extends on the entire side wall of the stack 18, for example on the entire side wall of the layer 20, of the layer 22 and of the layer 24. The upper face of the vertical part of element 26 is for example coplanar with the upper face of the stack 18.

The element 28 is located on the layer 14. More specifically, the horizontal part of the element 28 extends on the layer 14, preferably to the foot of the side wall of the stack 18 opposite to the wall on which lies element 26. Thus, the lower face of the horizontal part of the element 28 is only in contact with the layer 14. The vertical part of element 28 extends on the side wall of the stack 18. More specifically, the vertical part of the element 28 extends on the side wall of the stack 18 opposite to the wall on which lies the element 26. Preferably, the vertical part of element 28 extends on the entire side wall of the stack 18, for example on the entire side wall of the layer 20, of the layer 22 and of the layer 24. Thus, the vertical part of the element 28 extends on the entire height of the side wall of the stack 18, and reaches the level of the upper face of the stack 18.

The cells 12, more specifically the stacks 18 and associated elements 26, 28, are surrounded by an insulating layer 30. Thus, layer 30 separates the cells 12, more specifically the stacks 18 and associated elements 26, 28, from each other. Each stack 18 preferably corresponds to a single cell 12. The stacks 18 of each cell include side walls, not covered by the elements 26, 28, covered by the layer 30.

Layer 30 extends on the entire height of the stack 18. Thus, the upper face of the layer 30 is for example coplanar with the upper face of the stack 18, and more specifically with the upper face of the layer 24.

The device 10 includes an insulating layer 32. The insulating layer 32 is for example in silicon oxide. The layer 32 corresponds for example to a layer in an interconnection network. The layer 32 is crossed by the conductive elements 34. The elements 34 are for example in metal, for example in copper. The layer 32 and elements 34 correspond for example to a level of metallization, for example the level MX+1. The cells 12 are thus located between two successive levels of the interconnection network.

The elements 34 preferably extend on the entire height of the layer 32. The elements 34 have for example an upper end coplanar with the upper face of the layer 32. Each element 34 has a lower end in contact with the upper face of an element 28. The elements 34 have for example an upper end coupled, by a via, with a metallization of a level MX+2.

During the programming of each memory cell, a current is sent between element 16, for example coupled to a wordline, and element 34, for example coupled to a bitline. The current causes the resistive elements 26, 28 to heat thereby heating the phase change material of the layer 22. The phase change material thus switches between the crystalline phase and the amorphous phase

Preferably, the layer 22 and the elements 26, 28 have dimensions allowing them to create a thermal confinement in the layer 22. For example, the layer 22 has a thickness less than the thickness of the vertical portion of the elements 26, 28, for example between 5 nm and 20 nm. Alternatively, the elements 26, 28 may be in a less resistive material than the material of the layer 22, for example in tungsten or in titanium nitride.

The thickness of the stack 18 may be such that the distance between the layers 14 and 32 corresponds to the thickness of a level of interconnection network in CMOS (Complementary metal-oxide-semiconductor) technologies. For example, the stack 18 has a thickness between 100 nm and 700 nm.

FIG. 2, FIG. 3, FIG. 4, FIG. 5, FIG. 6 and FIG. 7 show the steps, preferably successive, in a manufacturing method of the embodiment of FIG. 1.

FIG. 2 shows a step of an example of a manufacturing method for the device of FIG. 1.

This step includes a step of formation of the level of metallization MX including the elements 16.

This step includes the formation of the insulating layer 14. Cavities crossing through the layer 14 are formed at the locations of the elements 16. The cavities are then filled with the material of the elements 16, for example a metal, preferably copper or tungsten, so as to form said elements 16. The cavities are filled so that the material of elements 16 is not located outside the cavities.

FIG. 3 shows a step of an example of a manufacturing method for the device of FIG. 1.

During this step, a stack 36 of layers is formed on layer 14 and on elements 16. Stack 36 includes, in this order from layer 14:
an insulating layer 38;
a layer 40 in phase change material; and
an insulating layer 42.

The insulating layer 38 is in a material of the portion of layer 20 of the stack 18 of FIG. 1, for example in silicon nitride. The layer 40 is in the material of the layer 22 of stack 18 of FIG. 1. The layer 42 is preferably in the same material as the layer 24 of the stack 18 of FIG. 1, for example in silicon nitride.

Similarly, the thickness of the layer 38 corresponds to the thickness of layers 20 of FIG. 1. The thickness of the layer 40 corresponds to the thickness of layers 22 of FIG. 1. The thickness of the layer 42 corresponds to the thickness of layers 24 of FIG. 1.

FIG. 4 shows a step of an example of a manufacturing method for the device of FIG. 1.

During this step, etching is carried out to form cavities 44 in the stack 36. Each cavity 44 crosses through the stack 36. Thus, the bottom of cavities 44 corresponds to the level of the upper face of the layer 14. The bottom of the cavities 44 thus includes portions of the upper faces of the layer 14 and the elements 16.

The cavities 44 form strips between them from stack 36. The stack 36 is etched so as to form a strip 46 for each wordline, for example for each element 16 corresponding to a wordline. Each strip 36 includes a strip 48 of layer 38 corresponding to the layer 20 of stacks 18 of cells of the wordline, a strip 50 of layer 40 corresponding to layer 22 of stacks 18 of cells of the wordline and a strip 52 of layer 42 corresponding to layer 24 of stacks 18 of cells of the wordline. The side walls of the cavities 44 correspond to the sides of the strips 50.

Each strip 50 partially covers an element 16 and partially covers layer 14. Each strip 50 preferably extends on the entire length of element 16.

Each strip 50 includes a side wall, or a side, corresponding to the wall on which lies element 26 of FIG. 1 and extending on the element 16, in the direction of the wordline. Thus, each element 16 is partially covered by one, preferably only one, strip 50. Each strip includes a side wall, or a side, corresponding to the wall on which lies the element 28 of FIG. 1 and extending on the layer 14.

FIG. 5 shows a step of an example of a manufacturing method for the device of FIG. 1.

During this step, a layer 54 in the material of elements 26 and 28 is formed conformally on the whole of the structure. The layer 54 covers in particular the side walls of stack 46 and the portions of layer 14 and elements 16 located at the feet of stacks 46. In particular, the layer 54 covers the side walls of layers 50. Layer 54 preferably has a substantially constant thickness. The thickness of the layer 54 is substantially equal to the thickness of the horizontal and vertical parts of the elements 26 and 28 of FIG. 1.

The step of FIG. 5 further includes the formation of spacers 56. The spacers cover the layer 54 at the walls of the cavities 44 and at the foot of the walls, so as to cover the portions of the layer 54 forming the elements 26 and 28.

FIG. 6 shows a step of an example of a manufacturing method for the device of FIG. 1.

The step of FIG. 6 includes a step of anisotropic etching of the layer 54, and more specifically of the portions of layer 54 not located under the spacers. The L-shaped elements 26 and 28 are thus formed. Each cavity 44 preferably includes two L-shaped elements 26 or 28 preferably one element 26 and one element 28, located on walls opposite to the cavity 44. Each element 26 or 28 formed during this step preferably extends on the entire length of strip 46. The portion of the level 54 located between the elements 26, 28 is removed during this step, the elements 26, 28 thus not being in contact with each other.

The step of FIG. 6 further includes the individualization of cells 12. More specifically, the strips 46 and the corresponding elements 26 and 28, are etched so as to separate the cells intended to be coupled by the same wordlines.

The step of FIG. 6 further includes the formation of an insulating layer 58. The layer 58 is in the material of layer 30. The layer 58 and spacers 56 form the layer 30.

The layer 56 laterally surrounds the cells 12. In particular, layer 58 covers the side walls of the stacks 18 not covered by elements 26 and 28. The thickness of the layer 58 is substantially equal to the height of the stacks 18. The upper face of the layer 58 is thus coplanar with the upper face of the stacks 18 and the elements 28. The layer 58 does not cover the upper ends of the vertical parts of the elements 28.

FIG. 7 shows a step of an example of a manufacturing method for the device of FIG. 1.

This step includes a step of formation of the level of metallization MX+1 including the elements 34.

This step includes the formation of the insulating layer 32. Cavities crossing through the layer 32 are formed at the locations of the elements 34. More specifically, a cavity is formed so as to expose the upper end of each element 28. The cavities are then filled with the material of the elements 34, for example a metal, preferably copper or tungsten, so as to form said elements 34. The cavities are filled so that the material of the elements 34 is not located outside the cavities.

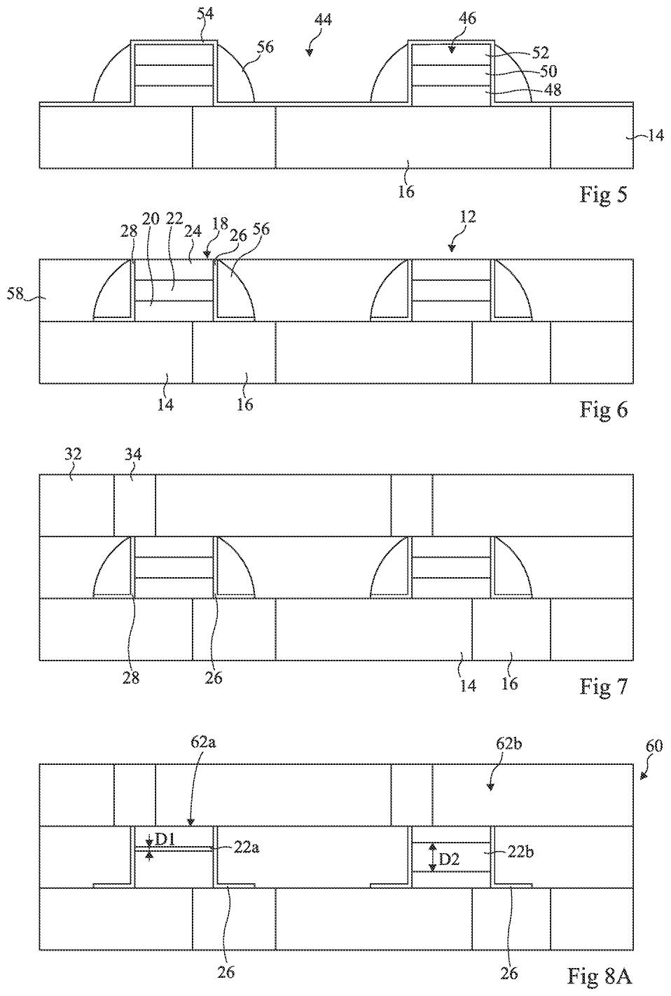

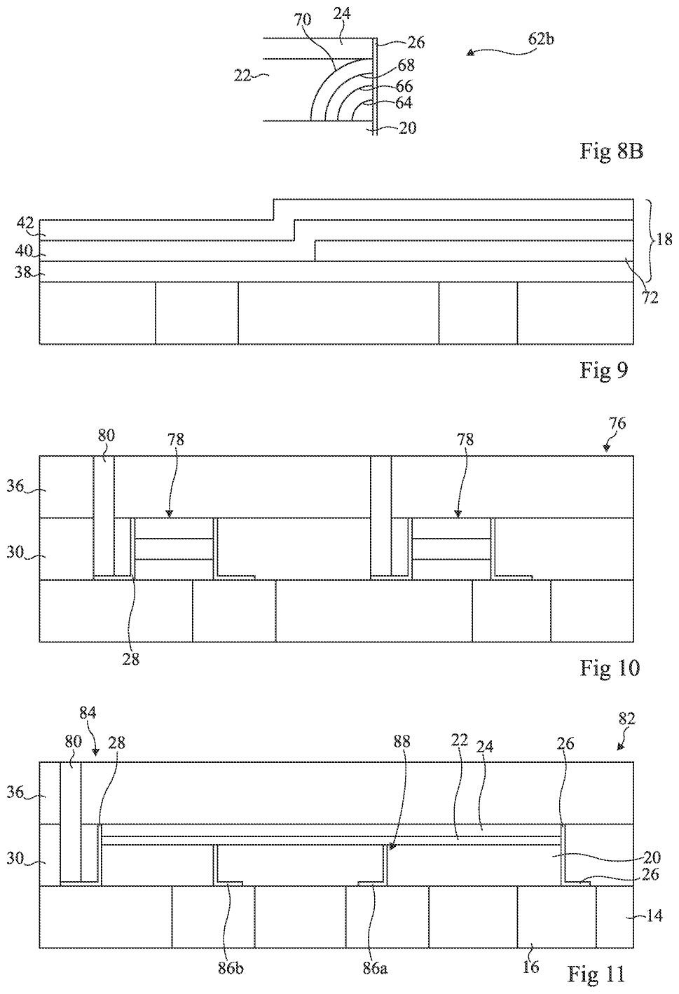

FIG. 8A shows another embodiment of an electronic device including memory cells 62a, 62b.

The device 60 includes the elements of the device 10 which will not be described in detail.

The device 60 differs from the device 10 in that the device 60 includes at least one cell 62a and at least one cell 62b. Cell 62a includes a layer 22a, corresponding to layer 22 of FIG. 1, having a thickness D1. Cell 62b includes a layer 22b, corresponding to layer 22 of FIG. 1, having a thickness D2. The thicknesses D1 and D2 are different. The thickness D1 is smaller than the thickness D2. For example, the thickness D1 is substantially twice as small as the thickness D2.

The cells 62a are memory cells with two states. In other words, the cells 62a may be programmed so as to contain one value among two values, for example binary values ‘0’ and ‘1’. The thickness D1 is for example between 5 nm and 50 nm. Thus, when a current passes through cell 62a, for example a current between 10 μA and 100 μA, all the phase change material in contact with element 26 switches between the amorphous phase and the crystalline phase. Thus, the cell 62a includes two states: a first state in which layer 22a is entirely in the amorphous phase and a second state in which all the phase change material in contact with element 26 is in the crystalline phase.

The cells 62b are multiple state memory cells, for example at least three states. In other words, cells 62b may be programmed so as to contain one value among at least three values. The thickness D2 is for example between 10 nm and 100 nm. Thus, when a current passes through cell 62b, for example a current between 10 μA and 100 μA, at least a part of the phase change material in contact with element 26 switches between the amorphous phase and the crystalline phase. Thus, the cell 62a includes various states described in more detail in relation to FIG. 8B.

FIG. 8B shows various states of an example of a memory cell according to the embodiment of FIG. 8A.

FIG. 8B shows part of a cell 62b. More specifically, FIG. 8B shows a part of an element 26 and a part of a stack 18. FIG. 8B shows a part of the layer 22, more specifically the part in contact with the element 26.

In the example of FIG. 8B, the cell 62b may contain one value among five distinct values. Each value corresponds to a value of resistivity between the element 16 and the element 34, and more specifically between the element 26 and the element 28.

FIG. 8B includes contours 64, 66, 68, 70 corresponding to the portion of the layer 22 switching from the amorphous phase to the crystalline phase during programming of one of the values.

The cell 62b is programmed so as to contain a first value when the layer 22 is entirely amorphous. No current intended to switch the phase of the layer 22 has been applied between the elements 26 and 28.

The cell 62b is programmed so as to contain a second value when the layer 22 includes a portion delineated by the contour 64, having switched to the crystalline phase. Said portion is for example located at the lower corner of the layer 22 in contact with the element 26. Said portion is for example obtained by applying, between the elements 26 and 28, a current having a value within a first range. The resistance between the element 26 and the element 28 is thus higher than the value indicating the first value and indicates that the second value has been programmed.

The cell 62b is programmed so as to contain a third value when the layer 22 includes a portion delineated by the contour 66, having switched to the crystalline phase. Said portion is for example located at the lower corner of the layer 22 in contact with the element 26. Said portion is larger than the portion corresponding to the second value. Said portion includes for example the portion corresponding to the second value. Said portion is for example obtained by applying, between the elements 26 and 28, a current having a value within a second range, the values of the second range being for example higher than the values of the first range. The resistance between the element 26 and the element 28 is thus higher than the value indicating the second value and indicates that the third value has been programmed.

The cell 62b is programmed so as to contain a fourth value when the layer 22 includes a portion delineated by the contour 68, having switched to the crystalline phase. Said portion is for example located at the lower corner of the layer 22 in contact with the element 26. Said portion is larger than the portion corresponding to the third value. Said portion includes for example the portion corresponding to the third value. Said portion is for example obtained by applying, between the elements 26 and 28, a current having a value within a third range, the values of the third range being for example higher than the values of the second range. The resistance between the element 26 and the element 28 is thus higher than the value indicating the third value and indicates that the fourth value has been programmed.

The cell 62b is programmed so as to contain a fifth value when the layer 22 includes a portion delineated by the contour 68, having switched to the crystalline phase. Said portion corresponds for example to the entire wall of the layer 22 in contact with the element 26. Said portion is larger than the portion corresponding to the fourth value. Said portion is for example obtained by applying, between the elements 26 and 28, a current having a value within a fourth range, the values of the fourth range being for example higher than the values of the third range. The resistance between the element 26 and the element 28 is thus higher than the value indicating the fourth value and indicates that the fifth value has been programmed.

FIG. 9 shows a step in the manufacturing method of the embodiment of FIG. 8.

The manufacturing method of the device 60 is identical to the method described in relation to FIGS. 2 to 7, except for the step of FIG. 3 which is replaced by the step of FIG. 9. The step of FIG. 9 differs from the step of FIG. 3 in that the step of FIG. 3 includes, between the formation of the layer 38 and the formation of the layer 40, the formation of a layer 72 at the locations of the cells 62b. The layer 74 is not located at the locations of the cells 62a.

The thickness of the layer 74 corresponds to the difference between the thickness D1 and the thickness D2.

FIG. 10 shows another embodiment of the electronic device 76 including memory cells 78.

The device 76 includes the elements of the device 10 of FIG. 1 which will not be described in detail. The device 76 differs from the device 10 in that the device 76 does not include the elements 34. The device 76 includes conductive elements 80 crossing through the layer 36 and the layer 30 so as to reach the horizontal parts of the elements 28. The device 76 includes as many elements 80 as the cell 78. Each element 80 extends for example from the upper face of the layer 36 to the upper face of a horizontal part of the element 28.

FIG. 11 shows another embodiment of the electronic device 82 including memory cells 84. A single cell 84 is shown in FIG. 11.

The device 82 includes the elements of the device 76 of FIG. 10 which will not be described in detail. The device 82 differs from the device 76 in that each cell 84 includes at least one conductive element 86 located in the layer 20, preferably two elements 86a and 86b. Each element 86 is for example L-shaped. Each element 86 thus includes a horizontal part extending on, and in contact with, an element 16 distinct from the element 16 in contact with the element 26. Each element 86 also includes a vertical part extending from the element 16 to the layer 22, preferably, from the upper face of the element 16 to the lower face of the layer 22. The elements 86 are for example in the same material as the elements 26, 28.

The cell 82 is thus located above three elements 16. The three elements 16 are arranged in line, for example in the direction of a bitline.

The manufacturing method of the device 82 differs from the method described in relation to FIGS. 2 to 7 in that the manufacturing method of the device 82 includes the formation of three elements 16 per memory cell instead of one element 16. Furthermore, the manufacturing method of the device 82 differs from the method described in relation to FIGS. 2 to 7 in that the manufacturing method of the device 82 includes, between the formation of the layer 20 and the formation of the layer 22, the formation of the elements 86.

The formation of the elements 86 in the layer 20 is similar to the formation of the elements 26, 28 in the stack 18. The formation of the elements 86 includes the formation of a cavity 88 including a side wall at each element 86. The formation of the element 86 next includes the conformal formation of a conductive layer in the material of the elements 86 on the entire structure. The formation of the elements 86 includes the formation of spacers covering the portions of the conductive layer corresponding to the elements 86. The spacers extend for example from the upper face of the layer 14 to the upper face of the layer 20. The formation of the elements 86 next includes an anisotropic etching step to remove the portions of the conductive layer not protected by spacers. The cavity is then filled with an insulating material, for example the material of the layer 20.

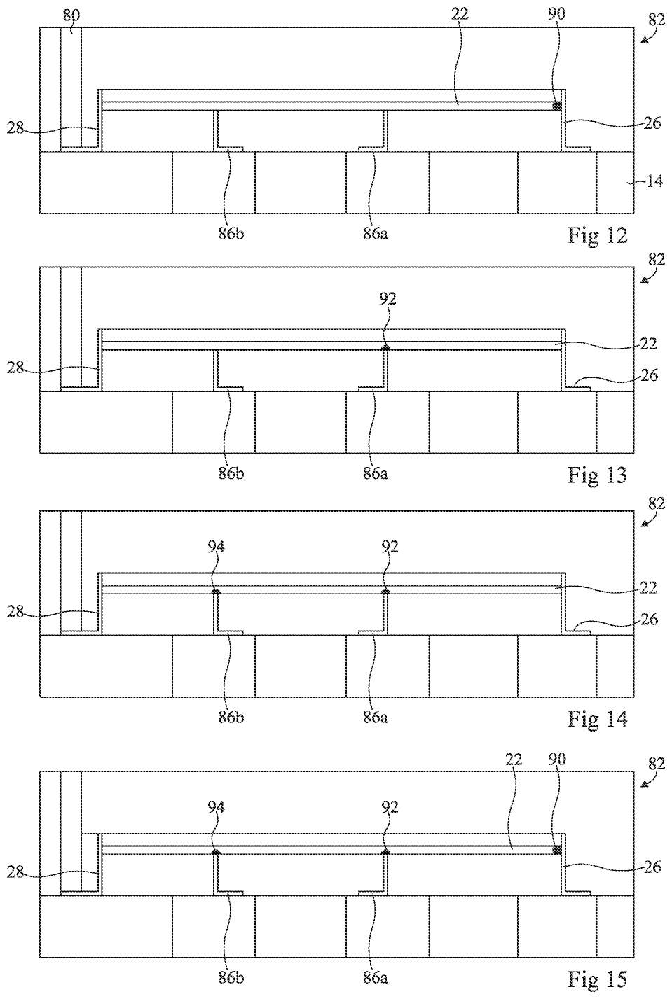

FIG. 12, FIG. 13, FIG. 14 and FIG. 15 show the possible states of the embodiment of FIG. 11.

FIG. 12 shows a first possible state of the device 82 of FIG. 11. More specifically, FIG. 12 shows the device 82 containing a first value.

The device 82 includes a region 90 in the layer 22, the material of the region 90 having switched from the amorphous phase to the crystalline phase. The region 90 is located at the interface between the layer 22 and the element 26.

The first value is programmed by applying a current between the elements 26 and 28. The value contained in the memory is read by determining the resistance between the elements 26 and 28. This resistance takes a first value in the case of FIG. 12.

FIG. 13 shows a first possible state of the device 82 of FIG. 11. More specifically, FIG. 13 shows the device 82 containing a second value.

The device 82 includes a region 92 in the layer 22, the material of the region 92 having switched from the amorphous phase to the crystalline phase. The region 92 is located at the interface between the layer 22 and the element 86a.

The second value is programmed by applying a current between the elements 86a and 28. The value contained in the memory is read by determining the resistance between the elements 26 and 28. This resistance takes a second value in the case of FIG. 13. Said second value of resistance is for example higher than the first value of resistance.

FIG. 14 shows a first possible state of the device 82 of FIG. 11. More specifically, FIG. 14 shows the device 82 containing a third value.

The device 82 includes a region 94 in the layer 22, the material of the region 94 having switched from the amorphous phase to the crystalline phase. The region 94 is located at the interface between the layer 22 and the element 86b. The device 82 further includes the region 92.

The third value is programmed by applying a current between the elements 86b and 28 and between the elements 86a and 28, for example simultaneously. The value contained in the memory is read by determining the resistance between the elements 26 and 28. This resistance takes a third value in the case of FIG. 14. Said third value of resistance is for example higher than the second value of resistance.

FIG. 15 shows a first possible state of the device 82 of FIG. 11. More specifically, FIG. 15 shows the device 82 containing a fourth value.

The device 82 includes the regions 90, 92 and 94. The fourth value is programmed by applying a current between the elements 86b and 28 and between the elements 86a and 28, and between the elements 26 and 28, for example simultaneously. The value contained in the memory is read by determining the resistance between the elements 26 and 28. This resistance takes a fourth value in the case of FIG. 15. Said fourth value of resistance is for example higher than the third value of resistance.

The device 82 of FIG. 11 may be in a fifth state, so as to contain a fifth value. In the fifth state, the layer 22 is entirely amorphous. The resistance between the elements 26 and 28 therefore takes a fifth value.

The device 82 of FIG. 11 may be in a sixth state, so as to contain a sixth value. In the sixth state, the layer 22 includes only the region 94.

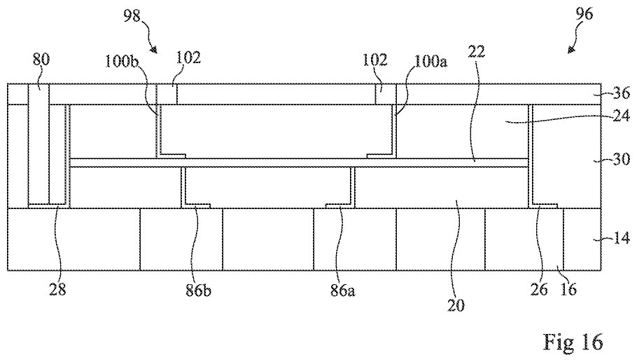

FIG. 16 shows another embodiment of the electronic device 96 including memory cells 98. A single cell 98 is shown in FIG. 16.

The device 96 includes the elements of the device 82 of FIG. 11 which will not be described in detail. The device 96 differs from the device 82 in that each device 96 includes at least one conductive element 100 located in the layer 24, preferably two elements 100a, 100b. Each element 100 is for example L-shaped. Each element 100 thus includes a horizontal part extending on, and in contact with, the layer 22. Each element 100 also includes a vertical part extending from the element 22 to the layer 32, preferably, from the upper face of the element 22 to the lower face of the layer 24. The elements 100 are for example in the same material as the elements 26, 28.

The device 96 includes an insulating layer 102. The elements 102 are for example in metal, for example in copper. The elements 102 are for example metallizations of the level MX+1. Each element 102 is in contact with the upper face of an element 100.

It is thus possible to program and to read several data in the cell 98. For example, one value is determined by the resistance between the elements 26 and 28, another value is determined by the resistance between the elements 86a and 100a and another value is determined by the resistance between the elements 86b and 100b.

For example, a first binary datum may be programmed between the elements 26 and 28, a second binary datum may be programmed between the elements 86a and 100a and a third binary datum may be programmed between the elements 86b and 100b. For example, the first datum is equal to a first value if the layer 22 is entirely in the amorphous phase and a second value if the layer 22 includes a region in the crystalline phase. The region in the crystalline phase corresponds for example to the region 90 of FIG. 12, to the region 92 of FIG. 13, to the region 94 of FIG. 14 or to a combination of regions 90, 92, 94. For example, the second value is equal to a first value if the layer 22 includes the region 92 and to a second value if the layer 22 does not include the region 92, for example if the portion of the layer 22 between the elements 86a and 100a is entirely in the amorphous phase. For example, the third value is equal to a first value if the layer 22 includes the region 94 and to a second value if the layer 22 does not include the region 94, for example if the portion of the layer 22 between the elements 86b and 100b is entirely in the amorphous phase.

An advantage of the embodiments previously disclosed is that it is possible to manufacture a memory cell that is incorporated in a level of metallization of an interconnection network.

An advantage of the embodiments disclosed is that the layer 22 is confined, for example that the layer 22 heats directly when a current crosses through it, instead of being heated indirectly by a resistive element that would heat and transfer heat. The loss of energy, and therefore the consumption of energy, is thereby reduced.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

A device (10, 60, 76, 82 96) includes a phase change memory cell (12, 62a, 62b, 78, 84, 98), the memory cell including a first stack of layers (18), the first stack of layers (18) including an intermediate layer (22) of phase change material, a lower insulating layer (20) and an upper insulating layer (24), the cell including L-shaped first (26) and second (28) conductive elements, the first element (26) extending on a first side wall of the first stack, the second element (28) extending on the second side wall of the stack opposite to the first wall.

A manufacturing method of a device (10, 60, 76, 82 96) including a phase change memory cell (12, 62a, 62b, 78, 84, 98), the method including a step of formation of a first stack of layers (18), the first stack of layers (18) including an intermediate layer (22) of phase change material, a lower insulating layer (20) and an upper insulating layer (24), the method may further include the formation of L-shaped first (26) and second (28) conductive elements, the first element (26) extending on a first side wall of the first stack, the second element (28) extending on a second side wall of the stack opposite to the first wall.

The intermediate layer may have a thickness between 5 nm and 50 nm.

The device may include an interconnection network, the cell (12, 62a, 62b, 78, 84, 98) being located between a lower level and an upper level of the interconnection network, the lower and upper levels being successive.

The first conductive element (26) may include a horizontal part lying on a third conductive element (16) of the lower level and a vertical part extending on the side wall of the first stack.

A fourth conductive element (34) of the upper level may be in contact with an upper end of a vertical part of the second element (28).

A fifth conductive element (80) may extend from the upper level to a horizontal part of the second conductive element (28).

The method may include the formation of the lower interconnection level, the formation of a second stack of layers (36) including a first layer (40) in a phase change material between two second insulating layers (38, 42), the formation of cavities extending through the second stack so as to form the first stack, a wall of each first stack being located on the third element.

The method may include the conformal formation of a third layer (54) in the material of the first and second elements, the formation of spacers (56) on the side walls of the first stack (18) and the etching of portions of the third layer that are not located under the spacers.

The device may include at least two cells (62a, 62b) whose intermediate layers (22a, 22b) have different thicknesses.

The intermediate layer (22a) of one of the cells (62a) may have a thickness between 5 nm and 50 nm and the intermediate layer (22b) of the other cells (62b) may have a thickness between 10 nm and 100 nm.

The method may include a step of formation of a layer (72) of thickness equal to the difference between the thicknesses of the intermediate layers of the two cells (62a, 62b) on the location of the cell having the greater thickness.

The device may include sixth L-shaped conductive elements (86) extending across the lower layer of the first stack.

The device may include seventh L-shaped conductive elements (100) extending across the upper layer of the first stack.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first phase change memory cell including:
a first stack of layers including a lower insulating layer, an upper insulating layer, and an intermediate layer of phase change material between the lower insulating layer and the upper insulating layer; and
a first L-shaped first conductive element extending on a first side wall of the first stack; and
a second L-shaped conductive element extending on a second side wall of the first stack opposite to the first side wall, wherein the layer of phase change material is configured so that at least portion of the layer of phase change layer is configured to change between an amorphous state and a crystalline state to determine a stored data value of the first phase change memory cell.

2. The device according to claim 1, wherein the intermediate layer has a thickness between 5 nm and 50 nm.

3. The device according to claim 1, comprising an interconnection network, the first phase change memory cell being located between a lower level and an upper level of the interconnection network, the lower and upper levels being successive.

4. The device according to claim 3, wherein the first conductive element includes a horizontal part lying on a third conductive element of the lower level and a vertical part extending on the first side wall of the first stack.

5. The device according to claim 4, wherein a fourth conductive element of the upper level is in contact with an upper end of a vertical part of the second element.

6. The device according to claim 5, wherein a fifth conductive element extends from the upper level to a horizontal part of the second conductive element.

7. The device according to claim 6, comprising sixth L-shaped conductive elements extending across the lower layer of the first stack.

8. The device according to claim 7, comprising seventh L-shaped conductive elements extending across the upper layer of the first stack.

9. The device according to claim 1, comprising a second phase change memory cell including:
a second stack of layers including a lower insulating layer, an upper insulating layer, an intermediate layer of phase change material between the lower insulating layer and the upper insulating layer;
an L-shaped third conductive element extending on a first side wall of the second stack; and
an L-shaped fourth conductive element extending on a second side wall of the second stack opposite to the first wall of the second stack, wherein the intermediate layer of the first stack has a difference thickness than the intermediate layer of the second stack.

10. The device according to claim 9, wherein the intermediate layer of the first stack has a thickness between 5 nm and 50 nm and wherein the intermediate layer of the second stack has a thickness between 10 nm and 100 nm.

11. The device of claim 1, comprising spacers covering the first conductive element and the second conductive element.

12. A method, comprising:
forming a first stack of layers of a first phase change memory cell of a device, the first stack including an intermediate layer of phase change material between a lower insulating layer and an upper insulating layer;
forming a first L-shaped conductive element extending on a first side wall of the first stack; and
forming a second conductive element extending on a second side wall of the first stack opposite to the first wall, wherein the layer of phase change material is configured so that at least portion of the layer of phase change layer is configured to change between an amorphous state and a crystalline state to determine a stored data value of the first phase change memory cell.

13. The method of claim 12, comprising:
forming a lower level of an interconnection network;
forming the first stack on the lower level of the interconnection network; and
forming an upper level of the interconnection network above the first stack, the lower and upper levels of the interconnection network being successive.

14. The method according to claim 13, comprising forming a plurality of third conductive elements in the lower interconnection level, wherein forming the first stack includes:
forming a blanket stack of the first layer of phase change material between two insulating layers on the lower interconnect level; and
forming, from the blanket stack, the first stack and a second stack of a second phase change memory cell by forming cavities extending through the blanket stack, a first sidewall of each first stack being located on a respective third conductive element.

15. The method according to claim 14, wherein the method comprises:
conformally depositing a third layer of a material of the first and second conductive elements on the first and second stacks;
forming spacers on the sidewalls of the first stack; and
forming, from the third layer, the first and second conductive elements by patterning the third layer with an etching process in a presence of the spacers.

16. The method according to claim 13, comprising forming a second stack of a second memory cell on the lower level of the interconnection network, the second stack including a lower insulating layer, an upper insulating layer, and an intermediate layer of phase change material between the lower insulating layer and the upper insulating layer, wherein the intermediate layer of the first stack is thicker than the intermediate layer of the second stack, wherein the first stack and the second stack have a same height.

17. A device, comprising:
an interconnection network including a lower interconnection level and an upper interconnection level;
a first phase change memory cell between the lower interconnection level and the upper interconnection level including:
a first lower insulating layer on the lower interconnection level;
a first L-shaped conductive element on a first sidewall of the first lower insulating layer and on a top surface of a first conductive interconnection element in the lower interconnection level; and
a second L-shaped conductive element on a second sidewall of the first lower insulating layer;
a second phase change memory cell including:
a second lower insulating layer on the lower interconnection level;
a third L-shaped conductive element on a first sidewall of the first lower insulating layer and on a top surface of a second conductive interconnection element in the lower interconnection level; and
a fourth L-shaped conductive element on a second sidewall of the first lower insulating layer; and
a layer of phase change material on a top surface of the first lower insulating layer, on a top surface of the second lower insulating layer, and extending unbroken between the first and second lower insulating layers, and in contact with a top surface of the first conductive element and with a top surface of the third conductive element.

18. The device of claim 17, wherein the layer of phase change material is in contact with a side surface of the second conductive element and with a side surface of the fourth conductive element.

19. The device of claim 18, comprising an upper insulating layer on the layer of phase change material and extending between the first phase change memory cell and the second phase change memory cell.

20. The device of claim 19, wherein the upper insulating layer is in contact with a side surface of the second conductive element and with a side surface of the fourth conductive element.
